(19) United States
(12) Patent Application Publication
(10) Pub. No.: US 2014/0212994 A1
(43) Pub. Date: Jul. 31, 2014

(54) SELF ALIGNED DUAL PATTERNING TECHNIQUE ENHANCEMENT WITH MAGNETIC SHIELDING

(71) Applicant: APPLIED MATERIALS, INC., Santa Clara, CA (US)

(72) Inventors: Hun Sang KIM, San Ramon, CA (US); Sang Wook KIM, Palo Alto, CA (US); Anisul H. KHAN, Santa Clara, CA (US)

(73) Assignee: APPLIED MATERIALS, INC., Santa Clara, CA (US)

(21) Appl. No.: 14/162,521

(22) Filed: Jan. 23, 2014

Related U.S. Application Data
(60) Provisional application No. 61/757,019, filed on Jan. 25, 2013.

(51) Int. Cl. H01L 21/67; H01L 21/32; H01L 21/66

(52) U.S. Cl. CPC H01L 21/67069; H01L 22/30; H01L 22/10; H01L 21/32
USPC 438/5; 156/345.3; 156/345.29; 156/345.24; 438/710

(57) ABSTRACT

Embodiments of the present disclosure generally provide apparatus and method for improving processing uniformity by reducing external magnetic noises. One embodiment of the present disclosure provides an apparatus for processing semiconductor substrates. The apparatus includes a chamber body defining a vacuum volume for processing one or more substrate therein, and a shield assembly for shielding magnetic flux from the chamber body disposed outside the chamber body, wherein the shield assembly comprises a bottom plate disposed between the chamber body and the ground to shield magnetic flux from the earth.

### CROSS-REFERENCE TO RELATED APPLICATIONS

This application claims benefit of U.S. Provisional Application Ser. No. 61/757,019 (Attorney Docket No. 20320L), filed Jan. 25, 2013, which is incorporated herein by reference.

### BACKGROUND

1. Field

Embodiments of the present disclosure generally relate to apparatus and methods for processing semiconductor substrates. More particularly, embodiments of the present disclosure relate to apparatus and method for shielding magnetic noises from plasma generated in a semiconductor substrate processing chamber.

2. Description of the Related Art

Processing chambers used in semiconductor processing generally have inherent non-uniformities of varying degrees depending on chamber structure and processing conditions. The inherent non-uniformities generally cause skews, which can be compensated by hardware or software adjustment. However, the skew caused by inherent non-uniformity of hardware sometimes overlays with non-uniformity cause by external factors, such as magnetic field of the earth, thermal and or magnetic field of surrounding processing chambers. The overlaid non-uniformities are difficult to compensate or adjust because the external factors may be random and difficult to predict.

Therefore, there is a need for apparatus and methods for reducing and compensating skews caused by both inherent non-uniformities and external factors.

### SUMMARY

Embodiments of the present disclosure generally provide apparatus and method for improving processing uniformity by reducing external magnetic noises.

One embodiment of the present disclosure provides an apparatus for processing semiconductor substrates. The apparatus includes a chamber body defining a vacuum volume for processing one or more substrate therein, and a shield assembly for shielding magnetic flux from the chamber body disposed outside the chamber body, wherein the shield assembly comprises a bottom plate disposed between the chamber body and the ground to shield magnetic flux from the earth.

Another embodiment of the present disclosure provides a method for processing a substrate. The method includes applying a shield between a processing chamber and the ground to shield the processing chamber from magnetic flux generated by the earth, measuring a process rate of a process recipe performed by the processing chamber, and determining a skew in the measured process rate. The method further includes adjusting one or more components of the processing chamber or one or more processing parameters according to the determined skew, and processing one or more substrates in the processing chamber.

Yet another embodiment of the present disclosure provides a method for processing a substrate. The method includes applying a shield around a processing chamber to shield the processing chamber from magnetic flux and measuring a processing rate of the processing chamber to obtain a skew, and adjusting one or more components of the processing chamber or one or more processing parameters to correct the skew. The method further includes etching a template mask disposed below a patterned mask to form both a narrow feature and a wide feature in the template mask, removing the patterned mask from the narrow feature while substantially retaining the patterned mask on the wide feature, and etching the template mask to thin the exposed narrow feature relative to the wide feature formed in the template mask.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic sectional view of a processing chamber according to one embodiment of the present disclosure.

FIG. 1B is a flow chart of a method according to one embodiment of the present disclosure.

FIGS. 2A-2F are schematic sectional view of a substrate being processed according to one embodiment of the present disclosure.

FIG. 3 is a flow chart of a method according to one embodiment of the present disclosure.

FIG. 4 includes schematic plots showing processing results according to embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure provide apparatus and methods for improving processing uniformity in a semiconductor processing chamber, such as a plasma processing chamber. According to embodiments of the present disclosure, a shield assembly including a bottom plate positioned between a processing chamber and the ground may be applied to the processing chamber. The bottom plate attenuates or even eliminates magnetic flux from the earth. The shield assembly may also include a top plate and sidewalls. The top plate, sidewalls and bottom plate form an enclosure where the processing chamber is positioned. By enclosing the processing chamber, the shield assembly effectively preventing environment magnetic flux from entering the processing volume of the processing chamber.

According to one embodiment of the present disclosure, processing rate may be measured and a skew determined while the shield assembly is applied around the processing chamber. With the environment magnetic flux substantially shielded by the shield assembly, the measured skew substantially represents non-uniformities that are inherent to the processing chamber, thus, can be compensated by adjusting one or more components of the processing chamber or adjusting one or more processing parameters. In one embodiment, one or more coils of an antenna assembly for generating a plasma inside the processing chamber may be adjusted to adjust plasma distribution, thus, compensate the skew. In another embodiment, upon compensation of the skew inherent to the processing chamber, processing uniformity may be improved. The improved uniformity may also enable adjustment of processing parameters, such as plasma bias voltage, to achieve processing effects that cannot be otherwise achieved.

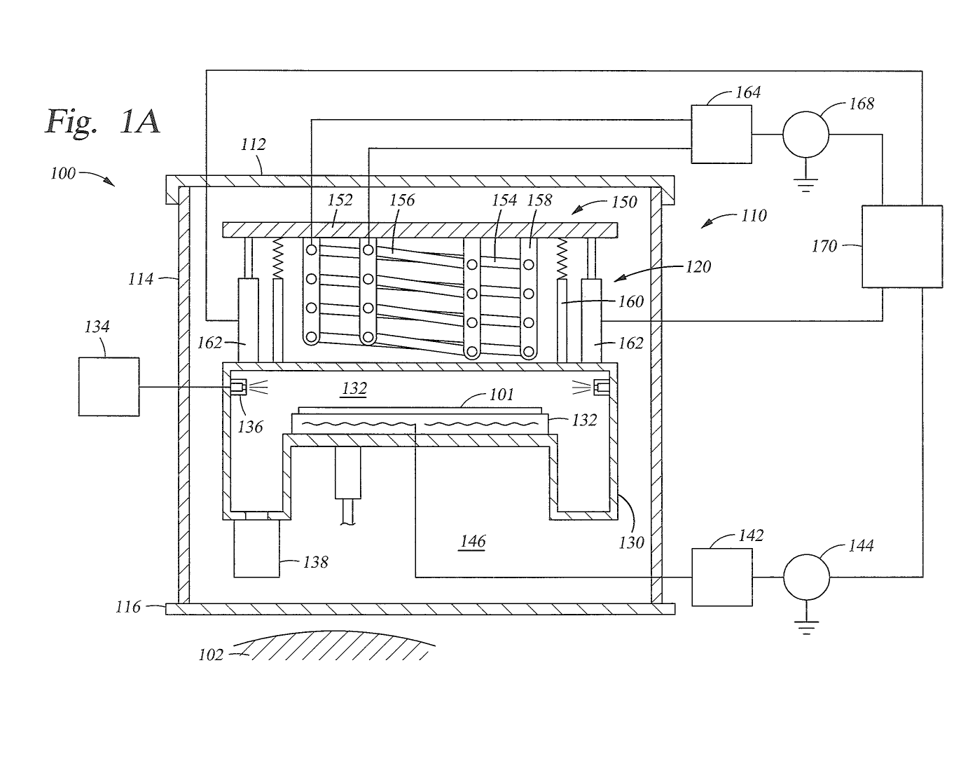

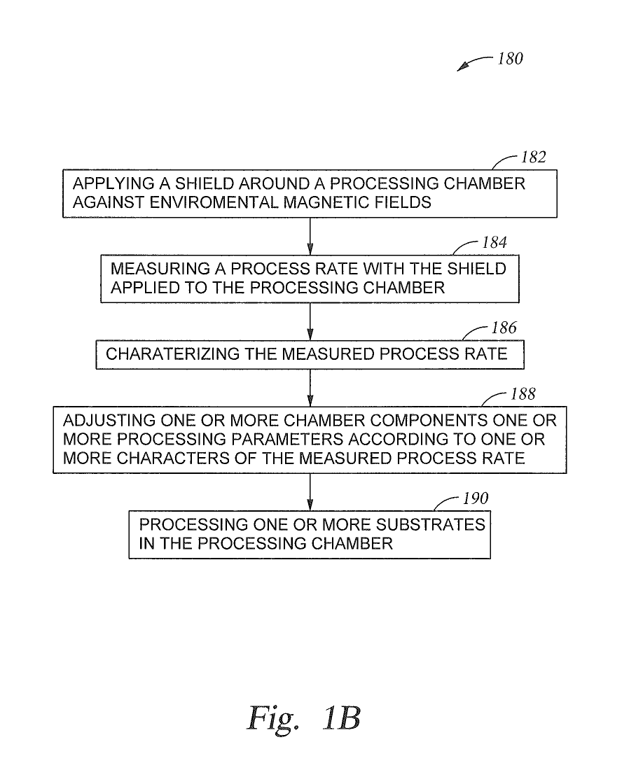

FIG. 1A is a schematic sectional view of a processing chamber 100 according to one embodiment of the present disclosure. The processing chamber 100 includes a chamber body 130, a plasma generator 120, and a shield assembly 110 disposed around the chamber body 130 and the plasma generator 120. The shield assembly 110 surrounds the chamber body 130 and the plasma generator 120 to prevent environmental magnetic flux from affecting processes

The chamber body 130 defines a processing volume 132. A substrate support 132 is disposed in the processing volume 132 for supporting a substrate 101 to be processed in the processing volume 132. A vacuum pump 138 may be coupled to the chamber body 130 to maintain a vacuum environment in the processing volume 132. A gas source 134 may be coupled to a gas distribution assembly 136. The gas distribution assembly 136 delivers one or more processing gas from the gas source 134 to the processing volume 132.

The plasma generator 120 generates plasma in the processing volume 132 for processing the substrate 101. In one embodiment, the plasma generator 120 may include an antenna assembly 150 for generating inductively coupled plasma in the processing volume 132. The antenna assembly 150 may include two antennas 154, 156 positioned above the chamber body 130. The antennas 154, 156 may be attached to a frame 152 by brackets 158. The antennas 154, 156 may be connected to a radio frequency (RF) power source 168 via a matching network 164 for plasma generation. In one embodiment, the antenna assembly 150 may include one or more motors 162 for adjusting the coils 154, 156 relative to the processing volume 132. The one or more motors 162 may also be used to adjust relative position of the coils 154, 156. In one embodiment, the motors 162 may be attached to the frame 152. Optionally, a shield 160 may be positioned around the antennas 154, 156.

The shield assembly 110 shields the processing volume 132 from external magnetic flux. Particularly, the shield assembly 110 includes one or more components positioned between the chamber body 130 and the ground 102 to shield any magnetic flux from the earth. In one embodiment, the shield assembly 110 may include a top plate 112, sidewalls 114 and a bottom plate 116. The top plate 112, sidewalls 114 and bottom plate 116 define an enclosure 146 to enclose the chamber body 130 therein. In one embodiment, the plasma generator 120 is also enclosed in the shield assembly 110. The bottom plate 114 positioned between the chamber body 130 and the ground 102 effectively attenuates magnetic flux from the earth, which may affect plasma distribution within the processing volume 132. Beside the magnetic flux from the earth, the shield assembly 110 also attenuates other environmental magnetic noises, such as noises from adjacent processing chambers, from entering the processing volume 132.

The shield assembly 110 may be formed from any material that is capable of attenuate magnetic flux from the environment. In one embodiment, the shield assembly 110 may be formed from a metal having high magnetic permeability and capable of shielding against static or low frequency magnetic fields. For example, the shield assembly 110 may be formed from stainless steel, such as 410 stainless steel, mu-metal, or soft-iron.

The shield assembly 110 may be formed in any suitable shape to enclose the chamber body 130 and the plasma generator 120 therein and to accommodate surroundings of the processing chamber 100. Sectional view of the sidewalls 114 may be circular or polygonal, such as rectangular or hexagonal.

The processing chamber further includes a controller 170 for monitoring and controlling the process performed therein. The shield assembly 110 allows the processing chamber 100 to process substrates with minimal affect from the environment. The controller 170 may connect and control the RF power source 168, a bias power source 144 via a matching network 142, or the motor 162. In one embodiment, the controller 170 may be used to monitor the processing rate across the substrate with the shield assembly 110 applied around the chamber body 130 and the plasma generation. The controller 170 may include a control program that determines a skew from the monitored process rate, and generates control signals to components of the processing chamber 100 to adjust the process rate and improve uniformity across the substrate.

FIG. 1B is a flow chart of a method 180 according to one embodiment of the present disclosure. The method 180 may be used to compensate a skew inherent to a processing chamber to achieve desired the processing effect, such as improving process uniformity.

Box 182 of the method 180 includes applying a shield around a processing chamber to shield the processing chamber from external magnetic flux. In one embodiment, the shield includes a plate disposed between the processing chamber and the ground to block any magnetic flux from the earth. The shield may be similar to the shield assembly 110 of the processing chamber 100.

Box 184 of the method 180 includes measuring a process rate across a substrate while running a process in the processing chamber having the shield applied. Since the shield effectively substantially prevents environmental magnetic noises from entering the processing chamber, non-uniformities in the measured process rate can be contributed substantially to causes inherent to the processing chamber itself, thus, may be addressed by adjusting the processing chamber alone. The measurement of box 184 may be performed in-situ using sensors in the processing chamber, such as the processing chamber 100. Alternatively, the measurement of box 184 may be performed in a metrology station independent from the processing chamber.

Box 186 of the method 180 includes characterizing the measured process rate. Characterizing the measured process rate may include a calculation to determine one or more characters of the measured process rate so that adjustment can be made to obtain desired process rate based on the one or more characters. In one embodiment, charactering the measured process may be determining a skew that reflects gradients of the non-uniformities in the measured process rate. In one embodiment, the skew may be used to generate signals for adjusting a plasma generator. Other characters of the measured process rate may be used according to process requirement.

Box 188 of the method 180 includes adjusting one or more components of the processing chamber or one or more processing parameters according to the one or more characters determined in box 186. The adjustment of box 188 may be used to improve processing results, such as improving uniformity across the substrate being processed, or achieving certain process results, such as edge thin or edge thick. In one embodiment, a plasma generator of the processing chamber may be adjusted according to the direction of the skew in the measured process rate to improve uniformity. For example, the plasma generator 120 in the processing chamber 100 may be adjusted by the controller 170. The plasma generator 120 may be adjusted by various approaches, such as adjusting positions of the antennas 154, 156 relative to the processing volume 132, adjusting relative positions between the antennas 154, 156, adjusting frequency, phase, or amplitude of the RF power source 168, or combinations thereof. In one embodiment, the positions of the antennas 154, 156 may be adjusted by moving the motors 162. Alternatively, other chamber components or processing parameters may be adjusted. For example, a bias power applied to the plasma may be adjusted. In the processing chamber 100, bias voltage applied to the substrate 101 by the bias power source 144 may be adjusted to improve process uniformity. For example, the bias voltage may be increased to allow lower plasma density in the processing volume 132, thus, improving controllability of the process rate across the substrate.

Box 190 of the method 190 includes processing one or more substrates in the processing chamber after adjustment with improved results. Generally, the same process recipe as performed in box 184 may be run for plurality of substrates for production with improved results. The process recipe may be any suitable ones such as etching, deposition, or epitaxial growth.

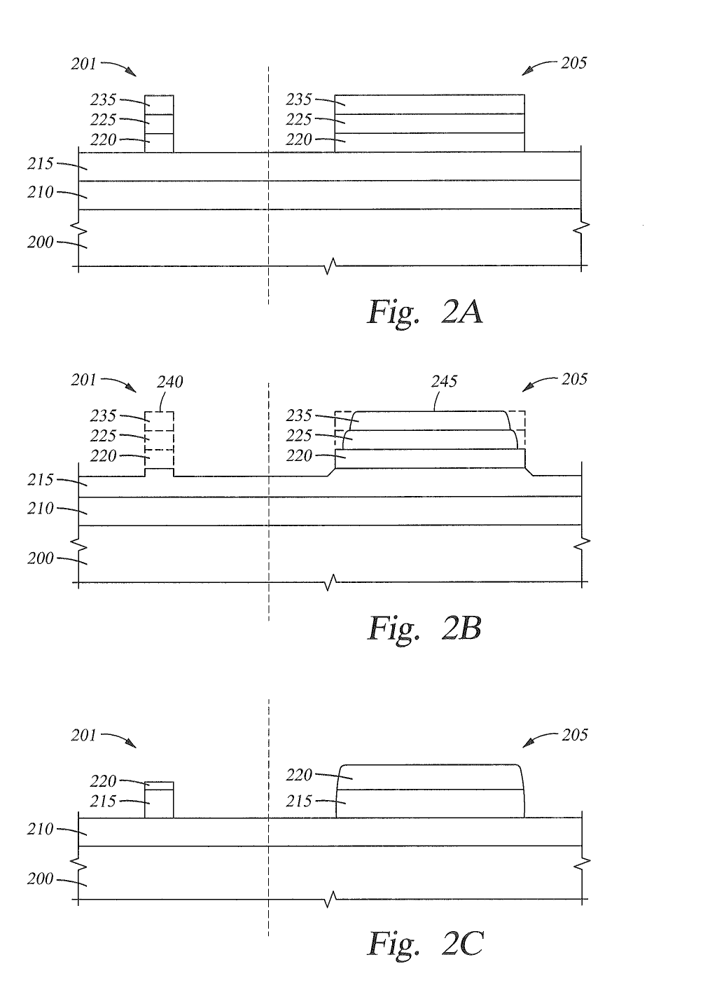

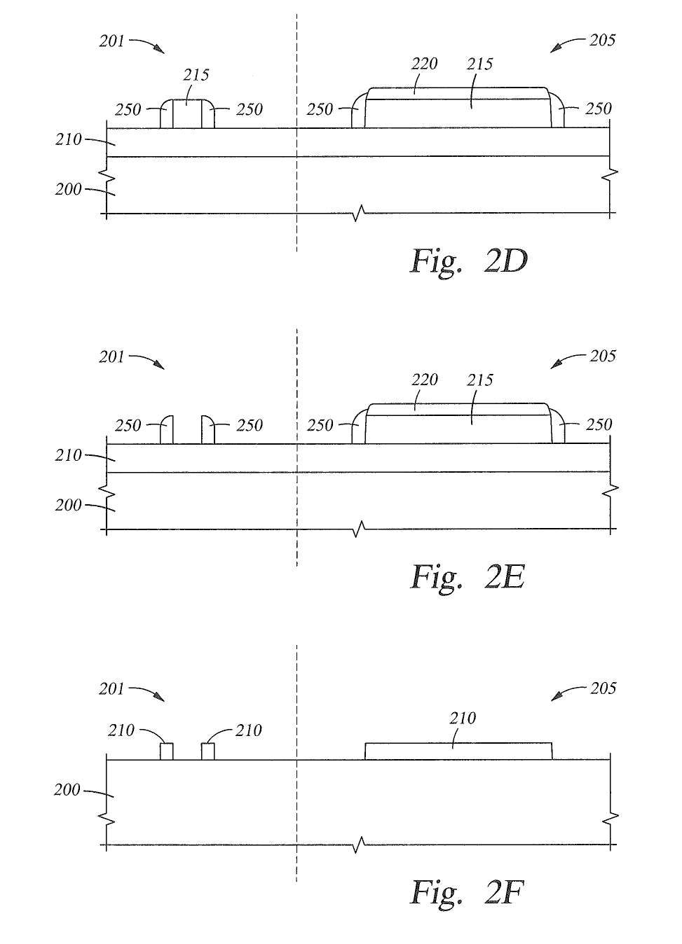

FIGS. 2A-2F are schematic sectional view of a substrate being processed by a method according to one embodiment of the present disclosure. Particularly, FIGS. 2A-2F illustrates etching and deposition processes in a selective self-aligned double patterning (SADP). The selective SADP generally includes using a photoresist pattern mask narrow features and wide features and formed in a single lithography operation to form a template mask by etching, then thinning the template mask by further etching, forming a spacer mask having half the pitch of the narrow feature in the template mask, and then forming features using the spacer mask. Usually, the narrow features are in a central cell region of a substrate, and the wide features are in a periphery edge of the substrate. The improved uniformity provided by apparatus and methods of the present disclosure enables the SADP process to be successful in even smaller critical dimensions. Particularly, embodiments of the present disclosure may be used to reduce pitting occurs in the narrow features formed by SADP process.

FIG. 2A depicts an exemplary partial cross-sectional view of device stack on a substrate 200. The device stack may be an integrated memory circuit device. The substrate 200 includes both a cell region 201 having narrow features and a periphery region 205 having wide features formed by etching a photoresist (PR) mask 235. The substrate 200 includes a spacer layer 210 wherein half picture spacer structures are to be formed. The spacer layer 210 may be any thin film layer suitable for the SADP process. A multi-layer template mask is form over the spacer layer 210. In one embodiment, the template mask may include a carbon hard based mask (CHM) 215 formed on the spacer layer 210, a dielectric anti-reflective coating (DARC) 220 formed over the CHM 215 and a bottom anti-reflective coating (BARO) 225 formed over the DARC 220. The PR mask 235 is over the BARC 225 and patterned by a photo lithography process. The PR mask 235 has narrow features 240 in the cell region 201 and wide features 245 in the periphery region 205. In one embodiment, the critical dimension of the wide features 245 may be about 5 to 10 time greater than the critical dimension of the narrow features 240.

In FIG. 2A, a first etch process has been performed to the substrate 200, and the pattern of the PR mask 235 is transferred to the BARC 225 and the DARC 220. The first etch process may be performed in a processing chamber according to embodiment of the present disclosure having a shield assembly applied and components or parameter adjusted after the shield assembly is applied to improve uniformity.

In FIG. 2B, a second etch process is performed to thin the template mask in the cell region 201 after the PR mask 235 in the cell region 201 is removed while the PR mask 235 in the periphery region 205 remains. As shown in the dashed lines, the BARC 225 and DARC 220 are removed during the second etch process while the BARC 225 and the DARC 220 in the periphery region 205 simply “thinned”. The CHM 215 is etched at the same rate in both the cell region 201 and the periphery region 205. Like the first etch process, the second etch process may be performed in a processing chamber according to embodiment of the present disclosure having a shield assembly applied and components or parameter adjusted after the shield assembly is applied to improve uniformity. The first and second etch process may be performed in the same processing chamber or a different processing chamber.

In FIG. 2C, the second etch process continues after the PR mask 235 in the periphery region 205 is removed and narrow and wide features formed in the CHM 215. The CHM 215 is exposed in the central cell region 201 and covered by the DARC 220 in the periphery region 205.

In FIG. 2D, sidewall spacer mask 250 is formed around the narrow and wide features of the CHM 215. The sidewall spacer mask 250 may be formed by first conformally depositing a spacer mask layer over the CHM 215, then anisotropically etching the conformal spacer mask layer to form the sidewall spacer mask 250.

In FIG. 2E, a third etching process is performed to remove the CHM 215 in the narrow features between the sidewall spacer mask 250. The pitch of the spacer sidewall mask 250 in the central cell region 201 is also most half of the pitch of the narrow features 240 in the PR mask 235, thus effectively doubling the structural density in the central cell region 201.

In FIG. 2F, a fourth etching process is performed to form spacers in the spacer layer 210 using the sidewall spacer mask 250 formed in FIG. 2E. The final result has narrow features in the central cell region 201 and wide features in the periphery region 205.

The etch processes described in FIGS. 2C-2F may also be performed in a processing chamber according to embodiment of the present disclosure having a shield assembly applied and components or parameter adjusted after the shield assembly is applied to improve uniformity. The various etch processes may be performed in the same chamber, or combinations of different chambers depending on the tool arrangement and/or process recipe.

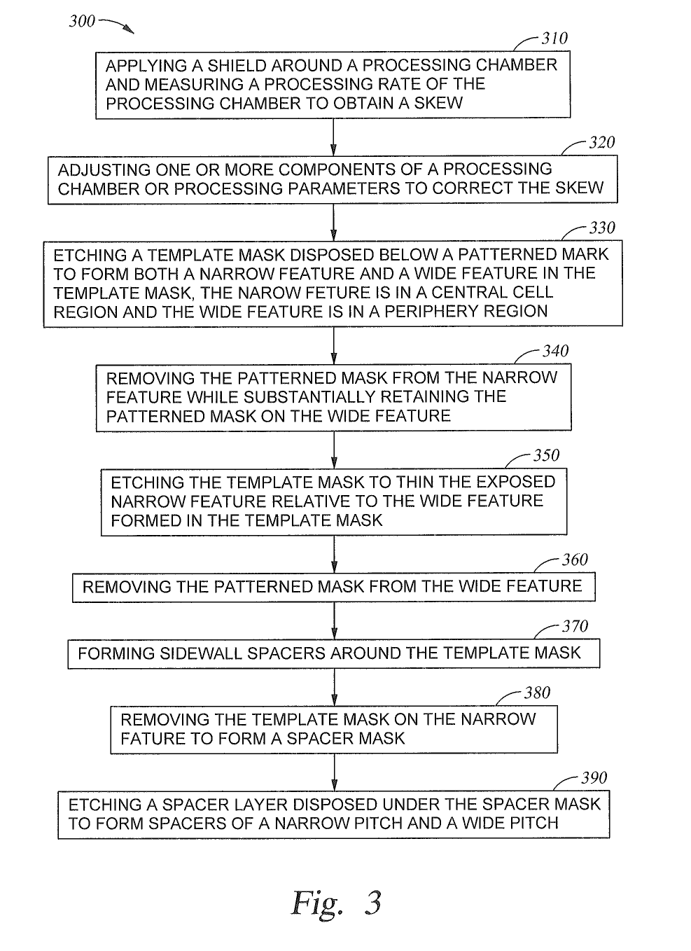

FIG. 3 is a flow chart of a method 300 of a SADP method according to one embodiment of the present disclosure. The method 300 may be performed using one or more processing chambers similar to the processing chamber 100 of FIG. 1A. The method 300 may be performed in a single processing chamber, or multiple processing chambers.

Box 310 of the method 300 includes applying a shield around a processing chamber and measuring a processing rate of the processing chamber to obtain a skew. The shield is similar to the shield assembly 110 of the processing chamber 100 that prevents environmental magnetic flux from entering the processing chamber. The shield may include a top plate, sidewalls and a bottom plate to enclose the processing chamber therein. In one embodiment, a processing rate may be measured and a skew determined to non-uniformity after excluding the external magnetic noises from the processing chamber.

Box 320 of the method 300 includes adjusting one or more components of the processing chamber or processing parameters to correct the skew. Similar to box 188 of the method 180, chamber components, such as antennas in a plasma generator, or processing parameters, such as bias voltage, may be adjusted to correct the skew and improve uniformity.

Depending on the number of processing chambers used, box 310 and box 320 may be performed for some or all the processing chambers used in the processes to follow.

Box 330 of the method 300 includes etching one or more layers in a template mask disposed below a patterned mask to form both a narrow feature and a wide feature in the template mask. The narrow feature may be arranged in a central cell region and the wide feature may be arranged a periphery region. FIG. 2A schematically illustrates a substrate stack after the etch process described in box 330.

Box 340 of the method 300 includes removing the patterned mask from the narrow feature while substantially retaining the patterned mask on the wide feature.

Box 350 of the method 300 includes etching the template mask to thin the exposed narrow feature relative to the wide feature formed in the template mask. FIG. 2B schematically illustrates a substrate stack after the etch processes described in box 340 and box 350.

Box 360 of the method 300 includes removing the patterned mask from the wide feature and etching through all layers of template mask to expose a spacer layers formed below, as shown in FIG. 2C.

Box 370 of the method 300 includes forming sidewall spacers around narrow and wide features in the template mask as shown in FIG. 2D.

Box 380 of the method 300 includes removing the template mask on the narrow feature to form a spacer mask from the sidewall spacers. The pitch of the spacer mask in the central region is almost half of the pitch of the narrow features in the photoresist pattern in box 330. FIG. 2E schematically illustrates a substrate stack after the etch process described in box 380.

Box 390 of the method 300 includes etching the spacer layer disposed under the spacer mask to form spacers of a narrow pitch and a wide pitch as shown in FIG. 2F.

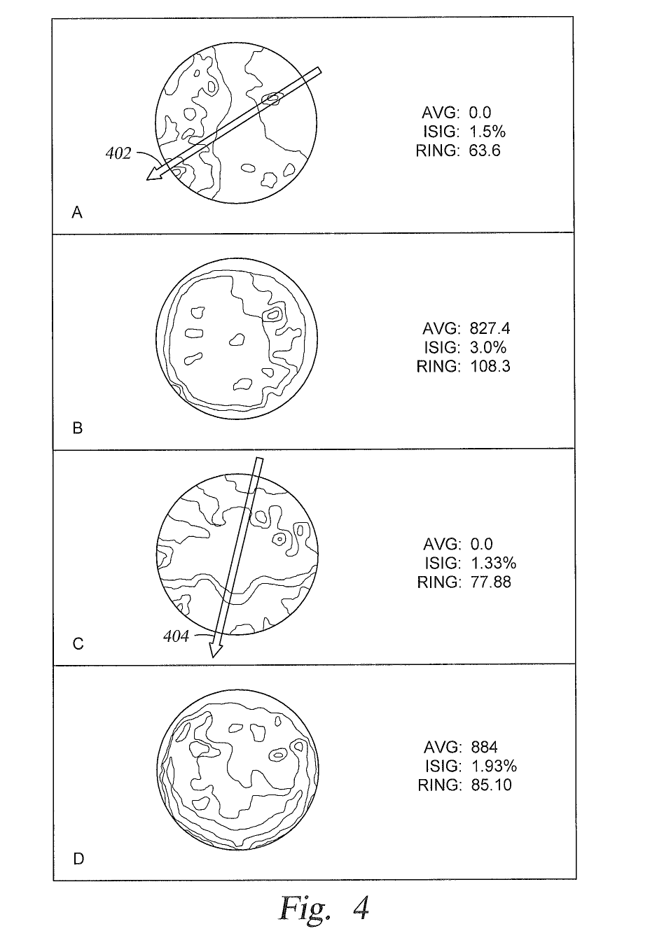

FIG. 4 includes schematic plots showing processing results according to embodiments of the present disclosure. FIG. 4 includes four contour plots. Plots (a) and (b) are reference data. Plot (a) schematically illustrates a skew of etch rate across a substrate for a tungsten etch in a plasma chamber without a shield. Arrow 402 indicates a direction of the skew. Antennas in the plasma chamber are then adjusted to correct the skew shown in plot (a). The same tungsten process is performed in the plasma chamber again without a shield after the adjustment. Plot (b) schematically illustrates an etch rate across the substrate of the tungsten etch after adjustment.

Plot (c) schematically illustrates a skew of etch rate across a substrate for the same tungsten etch in the same plasma chamber as in plots (a) and (b) but with a shield. The shield is formed a mu-metal and structurally similar to the shield assembly as described in FIG. 1A. Arrow 404 indicates a direction of the skew. The fact that the skews in plots (a) and (c) have different directions indicates the shield does remove some external noises from the plasma chamber. Antennas in the plasma chamber are then adjusted to correct the skew shown in plot (c). The same tungsten process is performed in the plasma chamber again with the shield after the adjustment. Plot (d) schematically illustrates an etch rate across the substrate of the tungsten etch after adjustment with the shield. In plot (d) the range of non-uniformity is 85.10 while in plot (b) the range of non-uniformity is 108.3. Therefore, the etch rate shown in plot (d) is more uniform that the etch rate shown in plot (b), indicating that apparatus and method according to the present disclosure improve uniformity.

Even though, embodiments of the present disclosure are described in association with inductive coupled plasma chamber used for etching, embodiments of the present disclosure may be used in combination with any processing chambers that use plasma to improve processing uniformities.

While the foregoing is directed to embodiments of the present disclosure, other and further embodiments of the disclosure may be devised without departing from the basic scope thereof, and the scope thereof is determined by the claims that follow.

1. An apparatus for processing semiconductor substrates, comprising:
a chamber body defining a vacuum volume for processing one or more substrate therein; and
a shield assembly for shielding magnetic flux from the chamber body disposed outside the chamber body, wherein the shield assembly comprises a bottom plate disposed between the chamber body and the ground to shield magnetic flux from the earth.

2. The apparatus of claim 1, wherein the shield assembly further comprising:
a top plate; and
sidewalls disposed between the top plate and the bottom plate, wherein the top plate, the bottom plate and the sidewalls form an enclosure, and the chamber body is disposed in the enclosure.

3. The apparatus of claim 2, wherein the shield assembly is formed from stainless steel, mu-metal, or soft iron.

4. The apparatus of claim 2, further comprising a plasma generator disposed inside the shield assembly for generating plasma within the vacuum volume.

5. The apparatus of claim 4, wherein the plasma generator is an antenna assembly disposed outside the chamber body for generating inductively coupled plasma within the vacuum volume.

6. The apparatus of claim 5, wherein the antenna assembly is disposed above the chamber body and below the top plate of the shield assembly.

7. The apparatus of claim 6, wherein the antenna assembly comprises an adjustment mechanism for moving an antenna relative to the chamber body to adjust plasma distribution within the vacuum volume.

8. The apparatus of claim 7, wherein the adjustment mechanism is a motor coupled to the antenna.

9. The apparatus of claim 8, further comprising a system controller coupled to the motor, wherein the system controller sends control signals to the motor to adjust the antenna according to a measurement of a plasma distribution in the vacuum volume.

10. A method for processing a substrate, comprising:
applying a shield between a processing chamber and the ground to shield the processing chamber from magnetic flux generated by the earth;
measuring a process rate of a process recipe performed by the processing chamber;
determining a skew in the measured process rate;
adjusting one or more components of the processing chamber or one or more processing parameters according to the determined skew; and
processing one or more substrates in the processing chamber.

11. The method of claim 10, wherein applying a shield comprises applying a shield assembly having a top plate, sidewalls and a bottom plate that form an enclosure, and the enclosure encloses the processing chamber therein.

12. The method of claim 11, wherein adjusting one or more components comprises adjusting a plasma generator of the processing chamber to adjust a plasma distribution within a vacuum volume of the processing chamber, and the plasma generator is positioned within the shield assembly.

13. The method of claim 12, wherein adjusting the plasma generator comprises adjusting an antenna assembly relative to the vacuum volume of the processing chamber.

14. The method of claim 13, wherein adjusting the antenna assembly comprises sending a control signal to a motor coupled to an antenna of the antenna assembly.

15. The method of claim 11, wherein adjusting one or more processing parameters comprises adjusting a bias source power applied to a plasma generated in a vacuum volume of the processing chamber.

16. The method of claim 10, wherein processing one or more substrate comprising etching one or more layers on a substrate using plasma generated in a vacuum volume of the processing chamber.

17. A method for processing a substrate, comprising
applying a shield around a processing chamber to shield the processing chamber from magnetic flux and measuring a processing rate of the processing chamber to obtain a skew;
adjusting one or more components of the processing chamber or one or more processing parameters to correct the skew;
etching a template mask disposed below a patterned mask to form both a narrow feature and a wide feature in the template mask;
removing the patterned mask from the narrow feature while substantially retaining the patterned mask on the wide feature; and
etching the template mask to thin the exposed narrow feature relative to the wide feature formed in the template mask.

18. The method of claim 17, wherein adjusting one or more components comprises adjust a plasma generator of the processing chamber to adjust a plasma distribution within a vacuum volume of the processing chamber, and the plasma generator is positioned within the shield and outside the processing chamber.

19. The method of claim 18, further comprising:
removing the patterned mask from the wide feature;
forming sidewall spacers around the template mask;
removing the template mask on the narrow feature to form a spacer mask; and
etching a spacer layer disposed under the spacer mask to form spacers of a narrow pitch and a wide pitch.

20. The method of claim 19, wherein forming sidewall spacers comprises:
increasing a bias voltage to applied to a plasma formed in the processing chamber; and
depositing a sidewall layers.
